(19) United States
(12) Patent Application Publication
(10) Pub. No.: US 2015/0107618 A1
(43) Pub. Date: Apr. 23, 2015

(54) OXYGEN CONTAINING PLASMA CLEANING TO REMOVE CONTAMINATION FROM ELECTRONIC DEVICE COMPONENTS

(71) Applicant: Applied Materials, Inc., Santa Clara, CA (US)

(72) Inventors: Jennifer Y. Sun, Mountain View, CA (US); Vahid Firouzdor, San Mateo, CA (US); Tom K. Cho, Los Altos, CA (US); Ying Zhang, Fremont, CA (US)

(73) Assignee: Applied Materials, Inc., Santa Clara, CA (US)

(21) Appl. No.: 14/059,405

(22) Filed: Oct. 21, 2013

(51) Int. Cl. H01J 37/32; B08B 7/00

(52) U.S. Cl. CPC H01J 37/32862; B08B 7/00
USPC 134/1.2; 156/345.24

(57) ABSTRACT

A gas comprising oxygen is supplied to a plasma source. A plasma jet comprising oxygen plasma particles is generated from the gas. A contaminant is removed from the component using the oxygen plasma particles.

### FIELD

Embodiments of the present invention pertain to the field of electronic device manufacturing, and in particular, to cleaning electronic device manufacturing components.

### BACKGROUND

In the semiconductor industry, electronic devices are typically fabricated by a number of manufacturing processes producing structures of an ever-decreasing size. Some manufacturing processes may generate particles, which frequently contaminate the semiconductor processing equipment, the substrate that is being processed that contributes to device defects. The contaminant particles can negatively impact the semiconductor device manufacturing, for example, cause defects in a semiconductor wafer, gas leakage, vacuum leakage, and other problems. The removal of the contaminant particles, e.g., residual carbon, organic contaminant particles, or other contaminants is rather challenging.

Generally, carbon is a common source of contamination on semiconductor device manufacturing equipment components. The carbon contamination can be caused by a residual carbon deposited during a process of electronic device manufacturing. The carbon contamination can also be caused by a by-product deposition during the component service inside a semiconductor tool. Additionally, some ceramic materials used for an electronic device manufacturing tend to react to carbon source gases in atmosphere to form undesirable carbonates.

Some of the existing methods to clean the semiconductor processing tools use wipe, water, acetone, or other solvents. Some of the existing cleaning methods can leave by-products, for example, carbon that further contaminates the tools. The existing cleaning methods cannot remove the contaminant particles located at the edges and corners of the semiconductor processing tools.

As such, the existing cleaning methods cannot fully remove the contaminants from the semiconductor processing tools, can be time consuming and costly.

### SUMMARY

Methods and apparatuses to provide oxygen containing plasma cleaning to remove contamination from electronic device processing chamber components are described.

In one embodiment, a gas comprising oxygen is supplied to a plasma source. A plasma jet comprising oxygen plasma particles is generated from the gas. A contaminant is removed from a component of an electronic device manufacturing equipment using the oxygen plasma particles.

In one embodiment, a gas comprising oxygen is supplied to a plasma source. A plasma jet comprising oxygen plasma particles is generated from the gas. A contaminant is removed from a component of an electronic device manufacturing equipment using the oxygen plasma particles. The contaminant is transformed into a volatile product using the oxygen plasma particles.

In one embodiment, a gas comprising oxygen is supplied to a plasma source. The gas can be an air, a pure oxygen, a mixture of oxygen with reactive gases, a mixture of oxygen with non-reactive gases, or any combination thereof. A plasma jet comprising oxygen plasma particles is generated from the gas. The contaminant is removed from the component using the oxygen plasma particles.

In one embodiment, a gas comprising oxygen is supplied to a plasma source. A plasma jet comprising oxygen plasma particles is generated from the gas. A contaminant is removed from a component of an electronic device manufacturing equipment using the oxygen plasma particles. The component is an electrostatic chuck, a nozzle, a showerhead, a chamber liner, a cathode sleeve, a sleeve liner door, a cathode base, a process ring, or any other component of a processing chamber for the electronic device manufacturing.

In one embodiment, a gas comprising oxygen is supplied to a plasma source. A plasma jet comprising oxygen plasma particles is generated from the gas. A contaminant on a component of an electronic device manufacturing equipment is determined. A parameter of the plasma source is adjusted based on the contaminant. The contaminant on the component is aligned to the plasma source. The contaminant is removed from the component of the electronic device manufacturing equipment using the oxygen plasma particles.

In one embodiment, a gas comprising oxygen is supplied to a plasma source. A plasma jet comprising oxygen plasma particles is generated from the gas. A contaminant is removed from a component of an electronic device manufacturing equipment using the oxygen plasma particles. The contaminant comprises at least one of a carbon and an organic material.

In one embodiment, a gas comprising oxygen is supplied to a plasma source. A plasma jet comprising oxygen plasma particles is generated from the gas. A contaminant is removed from a component of an electronic device manufacturing equipment using the oxygen plasma particles. The contaminant is removed under a vacuum condition.

In one embodiment, a gas comprising oxygen is supplied to a plasma source. A plasma jet comprising oxygen plasma particles is generated from the gas. A contaminant is removed from a component of an electronic device manufacturing equipment using the oxygen plasma particles. The contaminant is removed at an atmospheric pressure.

In one embodiment, an apparatus to clean a component of an electronic device manufacturing equipment comprises a fixture to hold the component. A plasma source is configured to receive a gas comprising oxygen. The plasma source is configured to generate a plasma jet comprising oxygen plasma particles from the gas. A processor is coupled to the plasma source. The processor has a first configuration to control the plasma source to remove a contaminant from the component using the oxygen plasma particles.

In one embodiment, an apparatus to clean a component of an electronic device manufacturing equipment comprises a fixture to hold the component. A plasma source is configured to receive a gas comprising oxygen. The plasma source is configured to generate a plasma jet comprising oxygen plasma particles from the gas. A processor is coupled to the plasma source. The processor has a first configuration to control the plasma source to remove a contaminant from the component using the oxygen plasma particles.

In one embodiment, an apparatus to clean a component of an electronic device manufacturing equipment comprises a fixture to hold the component. A plasma source is configured to receive a gas comprising oxygen. The plasma source is configured to generate a plasma jet comprising oxygen plasma particles from the gas. A processor is coupled to the plasma source. The processor has a first configuration to control the plasma source to remove a contaminant from the component using the oxygen plasma particles. The oxygen particles in the plasma jet are used to transform the contaminant into a volatile product.

In one embodiment, an apparatus to clean a component of an electronic device manufacturing equipment comprises a fixture to hold the component. A plasma source is configured to receive a gas comprising oxygen. The gas can be an air, a pure oxygen, a mixture of oxygen with reactive gases, a mixture of oxygen with non-reactive gases, or any combination thereof.

The plasma source is configured to generate a plasma jet comprising oxygen plasma particles from the gas. A processor is coupled to the plasma source. The processor has a first configuration to control the plasma source to remove a contaminant from the component using the oxygen plasma particles.

In one embodiment, an apparatus to clean a component of an electronic device manufacturing equipment comprises a fixture to hold the component. A plasma source is configured to receive a gas comprising oxygen. The plasma source is configured to generate a plasma jet comprising oxygen plasma particles from the gas. A processor is coupled to the plasma source. The processor has a first configuration to control the plasma source to remove a contaminant from the component using the oxygen plasma particles. The component is an electrostatic chuck, a nozzle, a showerhead, a chamber liner, a cathode sleeve, a sleeve liner door, a cathode base, a process ring, or any other component of a processing chamber for the electronic device manufacturing.

In one embodiment, an apparatus to clean a component of an electronic device manufacturing equipment comprises a fixture to hold the component. A plasma source has an inlet to receive a gas comprising oxygen. The plasma source has a mouth to output a plasma jet comprising oxygen plasma particles from the gas. A processor is coupled to the plasma source. A memory is coupled to the processor to store a parameter of the plasma source.

The processor has a first configuration to control the plasma source to remove a contaminant from the component using the oxygen plasma particles. The processor has a second configuration to determine the contaminant on the component. The processor has a third configuration to adjust the parameter of the plasma source based on the contaminant. The processor has a fourth configuration to align the contaminant on the component to the plasma source.

In one embodiment, an apparatus to clean a component of an electronic device manufacturing equipment comprises a fixture to hold the component. A plasma source is configured to receive a gas comprising oxygen. The plasma source is configured to generate a plasma jet comprising oxygen plasma particles from the gas. A processor is coupled to the plasma source. The processor has a first configuration to control the plasma source to remove a contaminant from the component using the oxygen plasma particles. The contaminant comprises at least one of a carbon and an organic material.

In one embodiment, an apparatus to clean a component of an electronic device manufacturing equipment comprises a fixture to hold the component. A plasma source is configured to receive a gas comprising oxygen. The plasma source is configured to generate a plasma jet comprising oxygen plasma particles from the gas. A processor is coupled to the plasma source. The processor has a first configuration to control the plasma source to remove a contaminant from the component using the oxygen plasma particles in a vacuum chamber.

In one embodiment, an apparatus to clean a component of an electronic device manufacturing equipment comprises a fixture to hold the component. A plasma source is configured to receive a gas comprising oxygen. The plasma source is configured to generate a plasma jet comprising oxygen plasma particles from the gas. A processor is coupled to the plasma source. The processor has a first configuration to control the plasma source to remove a contaminant from the component using the oxygen plasma particles at an atmospheric pressure.

In one embodiment, a contaminant on a component of an electronic device manufacturing equipment is determined. At least one parameter of a plasma source is adjusted based on the contaminant. The plasma source and the contaminant are aligned. A plasma jet comprising oxygen plasma particles is generated by the plasma source. The contaminant is removed from the component by the oxygen plasma particles in the plasma jet.

In one embodiment, a contaminant on a component of an electronic device manufacturing equipment is determined. At least one parameter of a plasma source is adjusted based on the contaminant. The plasma source and the contaminant are aligned. A plasma jet comprising oxygen plasma particles is generated by the plasma source. The contaminant is removed from the component by the oxygen plasma particles in the plasma jet. The contaminant is transformed into a volatile product using the oxygen plasma particles.

In one embodiment, a contaminant on a component of an electronic device manufacturing equipment is determined. At least one parameter of a plasma source is adjusted based on the contaminant. The plasma source and the contaminant are aligned. A plasma jet comprising oxygen plasma particles is generated by the plasma source. The contaminant is removed from the component by the oxygen plasma particles in the plasma jet. At least one parameter of the plasma source is a voltage, a pressure, a gas supplied to the plasma source, a distance to the contaminant, a travel speed, a type of a nozzle of the plasma source, an angle of the plasma jet, cleaning time, temperature, or any combination thereof.

In one embodiment, a contaminant on a component of an electronic device manufacturing equipment is determined. The contaminant is determined by measuring a helium leakage at the component. At least one parameter of a plasma source is adjusted based on the contaminant. The plasma source and the contaminant are aligned. The plasma source is aligned with the contaminant by moving at least one of the plasma source and the component. A plasma jet comprising oxygen plasma particles is generated by the plasma source. The contaminant is removed from the component by the oxygen plasma particles in the plasma jet.

In one embodiment, a contaminant on a component of an electronic device manufacturing equipment is determined. At least one parameter of a plasma source is adjusted based on the contaminant. The plasma source and the contaminant are aligned. A plasma jet comprising oxygen plasma particles is generated by the plasma source. The contaminant is removed from the component by the oxygen plasma particles in the plasma jet. The contaminant comprises at least one of a carbon and an organic material.

Other features of the present invention will be apparent from the accompanying drawings and from the detailed description which follows.

### BRIEF DESCRIPTION OF THE DRAWINGS

The embodiments as described herein are illustrated by way of example and not limitation in the figures of the accompanying drawings in which like references indicate similar elements.

FIG. 1A shows a block diagram of one embodiment of a processing chamber system.

FIG. 1B shows an insert illustrating a portion of the workpiece on the ESC depicted in FIG. 1A according to one embodiment.

FIG. 2A shows an image illustrating a substantially high level of carbon contamination detected on an outer diameter edge of the outer seal band using a scanning electron microscope (“SEM”) according to one embodiment.

FIG. 2B shows an image illustrating a substantially high level of carbon contamination detected on an inner diameter edge of the outer seal band using a scanning electron microscope (“SEM”) according to one embodiment.

FIG. 2C shows an image illustrating a substantially high level of carbon contamination detected on an outer diameter edge of the inner seal band using a scanning electron microscope (“SEM”) according to one embodiment.

FIG. 2D shows an image illustrating a substantially high level of carbon contamination detected at a middle of a mesa using a scanning electron microscope (“SEM”) according to one embodiment.

FIG. 2E shows an image illustrating a substantially high level of carbon contamination detected at an edge of a mesa using a scanning electron microscope (“SEM”) according to one embodiment.

FIG. 3A shows a three dimensional (“3D”) image illustrating a polymer build up detected on an outer seal band edge using a laser microscope according to one embodiment.

FIG. 3B shows a top view of the image depicted in FIG. 3A using a laser microscope.

FIG. 3C is a view showing a portion of the 3D image depicted in FIG. 3A using a laser microscope.

FIG. 3DA shows a graph illustrating a polymer build up depicted in FIG. 3A using a laser microscope.

FIG. 3DB shows a table illustrating a polymer build up depicted in FIG. 3A.

FIG. 4A is a side view illustrating a component placed on a fixture on a stage according to one embodiment.

FIG. 4B is a view similar to FIG. 4A, after a plasma jet comprising oxygen plasma particles is generated by a plasma source.

FIG. 4C is a view similar to FIG. 4B after cleaning the component.

FIG. 5 shows a block diagram of an apparatus to clean a component of an electronic device manufacturing equipment according to one embodiment.

FIG. 6 shows a block diagram of a plasma cleaning system according to one embodiment.

FIG. 7 is a flow chart of a method to clean a component of an electronic device manufacturing equipment according to one embodiment.

FIG. 8 illustrates curves showing a carbon contaminant concentration measured versus a distance from an edge of a component according to one embodiment.

FIG. 9 shows a block diagram of an embodiment of a data processing system to control the plasma cleaning system as described herein.

### DETAILED DESCRIPTION

In the following description, numerous specific details, such as specific materials, chemistries, dimensions of the elements, etc. are set forth in order to provide thorough understanding of one or more of the embodiments of the present invention. It will be apparent, however, to one of ordinary skill in the art that the one or more embodiments of the present invention may be practiced without these specific details. In other instances, semiconductor fabrication processes, techniques, materials, equipment, etc., have not been described in great details to avoid unnecessarily obscuring of this description. Those of ordinary skill in the art, with the included description, will be able to implement appropriate functionality without undue experimentation.

While certain exemplary embodiments of the invention are described and shown in the accompanying drawings, it is to be understood that such embodiments are merely illustrative and not restrictive of the current invention, and that this invention is not restricted to the specific constructions and arrangements shown and described because modifications may occur to those ordinarily skilled in the art.

Reference throughout the specification to “one embodiment”, “another embodiment”, or “an embodiment” means that a particular feature, structure, or characteristic described in connection with the embodiment is included in at least one embodiment of the present invention. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments.

Moreover, inventive aspects lie in less than all the features of a single disclosed embodiment. Thus, the claims following the Detailed Description are hereby expressly incorporated into this Detailed Description, with each claim standing on its own as a separate embodiment of this invention. While the invention has been described in terms of several embodiments, those skilled in the art will recognize that the invention is not limited to the embodiments described, but can be practiced with modification and alteration within the spirit and scope of the appended claims. The description is thus to be regarded as illustrative rather than limiting.

Methods and apparatuses to provide oxygen containing plasma cleaning to remove contamination from electronic device processing chamber components are described. A gas comprising oxygen is supplied to a plasma source. A plasma jet comprising oxygen plasma particles is generated from the gas. A contaminant is removed from a component of an electronic device manufacturing equipment using the oxygen plasma particles. In an embodiment, an atmospheric or oxygen containing plasma cleaning is used to advantageously remove the carbon contamination from the surface of the semiconductor chamber components.

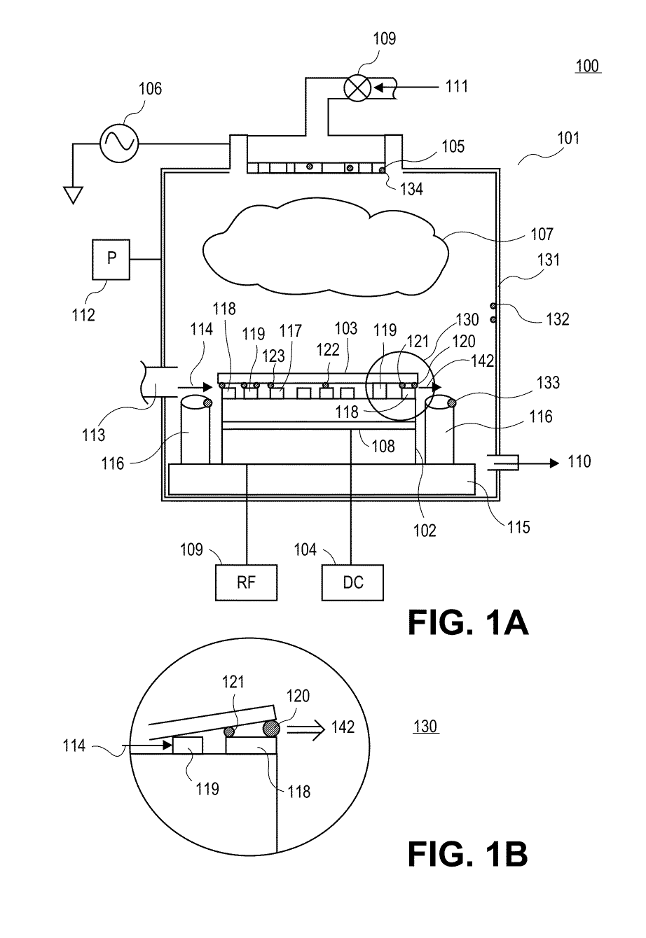

FIG. 1A shows a block diagram of one embodiment of a processing chamber system 100. As shown in FIG. 1A, system 100 has a processing chamber 101. An electrostatic chuck (“ESC”) 102 on a pedestal 115 is positioned in processing chamber 101. ESC 102 comprises a plurality of mesas, such as a mesa 117, an inner seal band 119, an outer seal band 118A. In an embodiment, pedestal 115 comprises a cooling base placed underneath the ESC 102. Generally, the mesas, inner seal band, an outer seal band are used to assist chucking the workpiece to the ESC. In an embodiment, the cooling base is an aluminum cooling base. In an embodiment, ESC 102 comprises an Al₂O₃ material, Y₂O₃, or other ceramic materials known to one of ordinary skill of electronic device manufacturing. In an embodiment, a ceramic puck on the top of the ESC is made from Al₂O₃. A DC electrode 108 is embedded into the ESC 102. A DC power supply 104 is connected to the DC electrode 108. A process ring 116 is placed on pedestal 115 to prevent arcing between the ESC and plasma source. In an embodiment, process ring 116 is a quartz ring. In other embodiments, process ring is made of insulating materials, for example Y₂O₃, materials similar to Y₂O₃, or any other insulating material known to one of ordinary skill of electronic device manufacturing.

As shown in FIG. 1A, a workpiece 103 is loaded through an opening 113 and placed on the mesas, the inner seal band 119 and outer seal band 118 of ESC 102. The workpiece can be a photomask, a semiconductor wafer, or other workpiece known to one of ordinary skill in the art of electronic device manufacturing. In at least some embodiments, the workpiece comprises any material to make any of integrated circuits, passive (e.g., capacitors, inductors) and active (e.g., transistors, photo detectors, lasers, diodes) microelectronic devices. The workpiece may include insulating (e.g., dielectric) materials that separate such active and passive microelectronic devices from a conducting layer or layers that are formed on top of them. In one embodiment, the workpiece is a semiconductor substrate that includes one or more dielectric layers e.g., silicon dioxide, silicon nitride, sapphire, and other dielectric materials. In one embodiment, the workpiece is a wafer stack including one or more layers. The one or more layers of the workpiece can include conducting, semiconducting, insulating, or any combination thereof layers.

As shown in FIG. 1A, a plasma 1007 is produced from one or more process gases 111 using a high frequency electric field. As shown in FIG. 1A, a pressure control system 112 provides a pressure to processing chamber 101. As shown in FIG. 10, chamber 101 is coupled to a RF source power 106, and to a bias RF power source 109 to produce plasma 107. As shown in FIG. 1A, chamber 101 is evacuated via an exhaust outlet 110. Exhaust outlet 110 is connected to a vacuum pump system (not depicted) to evacuate volatile products produced during processing in the chamber.

As shown in FIG. 1A, process gases 111 are supplied through a mass flow controller 109 to the chamber 101. When a plasma power is applied to the chamber 101, plasma 107 is formed in a processing region over workpiece 103. A plasma source power 106 is coupled to a plasma generating element 105 (e.g., showerhead, nozzle). A liner, such as a liner 131 extends along the walls of the chamber 101. As shown in FIG. 1A, contaminants, such as contaminants 120, 121, 122, 123, 132, 133, and 134 may be deposited on the system's components, e.g., an electrostatic chuck, a nozzle, a showerhead, a chamber liner, a cathode sleeve, a sleeve liner door, a cathode base, a process ring, or any other component of a processing chamber for the electronic device manufacturing. The contaminant can be a carbon contaminant, an organic contaminant, or both.

As shown in FIG. 1A, a predetermined amount of gas 114 is passed through a contact gap between the ESC 102 and the workpiece 103 to determine if the contaminant is deposited on the component. In an embodiment, gas 114 is helium. In other embodiments, gas 114 is any other gas known to one of ordinary skill in the art of electronic device manufacturing. FIG. 1B shows an insert 130 illustrating a portion of the workpiece on the ESC depicted in FIG. 1A according to one embodiment. As shown in FIG. 1B, contaminants, such as contaminant 120 and 121 are deposited between the portion of workpiece 103 and ESC 102. The workpiece 103 on the contaminants is positioned at an angle to the ESC 102 so that the workpiece 103 is not fully clamped to the chuck, as shown in FIG. 1B. In an embodiment, a gas leak 142 is measured through the contact gap, and if the gas leak is greater than a predetermined level, it is determined that the contaminant is deposited on the component, and the workpiece 103 is not fully clamped to the chuck. If the gas leak does not exceed a predetermined level, it is determined that there is no contaminant between the workpiece and the component and that the workpiece 103 is fully clamped to the chuck. In an embodiment, the helium leakage is measured, and if the helium leakage is greater than about 1.5 standard cubic centimeters per minute (“sccm”), it is determined that the contaminant is deposited on the component, and the workpiece is not fully clamped to the chuck.

In an embodiment, determining the contaminant involves determining at least one of the size and location of the contaminant. In an embodiment, the size and location of the contaminant is determined by measuring the amount of the leakage gas that passed through the contact gap between a workpiece and the component. In an embodiment, the size and locations of the contaminants on the components are detected using a scanning electron microscope (“SEM”) analysis, an energy-dispersive X-ray spectroscopy (“EDS”) analysis, or any other analysis known to one of ordinary skill in the art of electronic device manufacturing.

The system 100 may be any type of high performance semiconductor processing chamber known in the art, such as but not limited to an etcher, a cleaner, a furnace, or any other system to manufacture electronic devices. The system 100 may represent one of the systems manufactured by Applied Materials, Inc. located in Santa Clara, Calif.

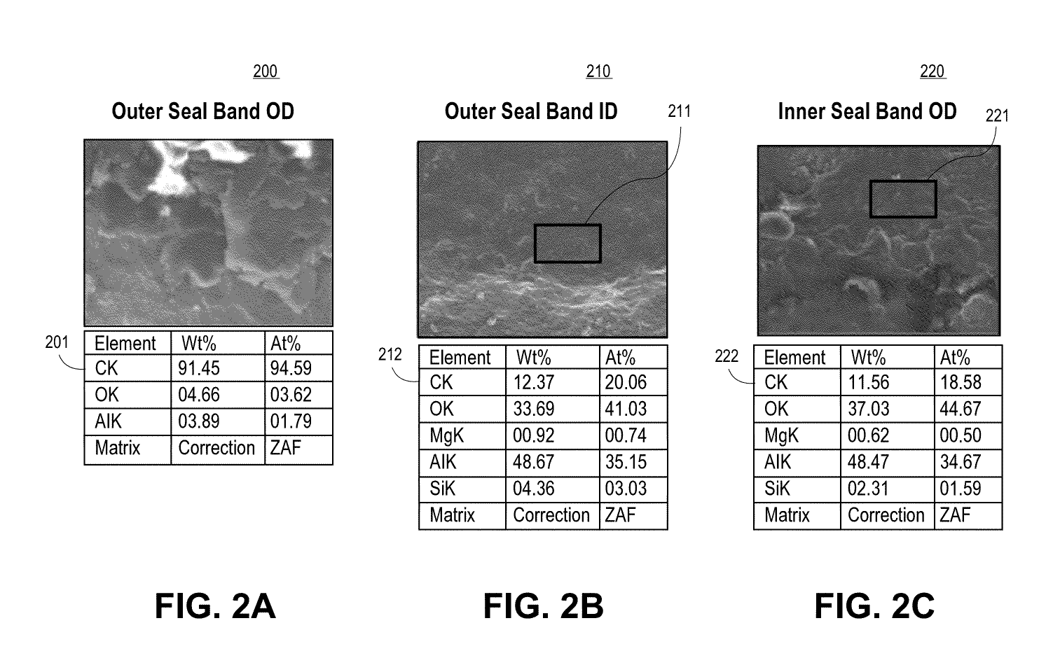

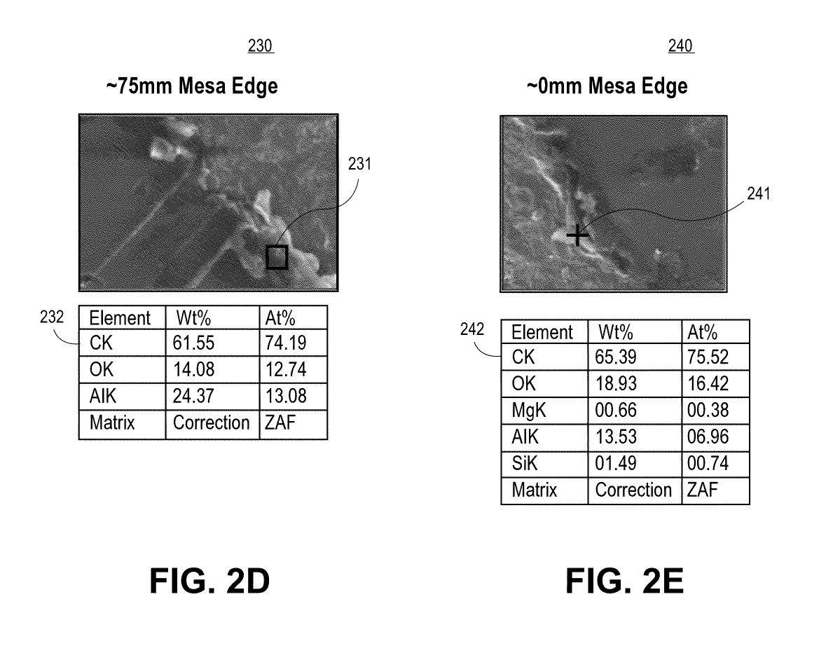

FIG. 2A shows an image 200 illustrating a substantially high level of carbon contamination detected on an outer diameter edge of the outer seal band using a scanning electron microscope (“SEM”) according to one embodiment. As shown in a table 201, the level of carbon contamination is more than 94 At %.

FIG. 2B shows an image 210 illustrating a substantially high level of carbon contamination detected on an inner diameter edge of the outer seal band using a scanning electron microscope (“SEM”) according to one embodiment. As shown in a table 212, the level of carbon contamination at a location 211 is more than 20 At %.

FIG. 2C shows an image 220 illustrating a substantially high level of carbon contamination detected on an outer diameter edge of the inner seal band using a scanning electron microscope (“SEM”) according to one embodiment. As shown in a table 222, the level of carbon contamination at a location 221 is more than 18 At %.

FIG. 2D shows an image 230 illustrating a substantially high level of carbon contamination detected at a middle of a mesa using a scanning electron microscope (“SEM”) according to one embodiment. As shown in a table 232, the level of carbon contamination at a location 231 is more than 74 At %.

FIG. 2E shows an image 240 illustrating a substantially high level of carbon contamination detected at an edge of a mesa using a scanning electron microscope (“SEM”) according to one embodiment. As shown in a table 242, the level of carbon contamination at a location 241 is more than 75 At %.

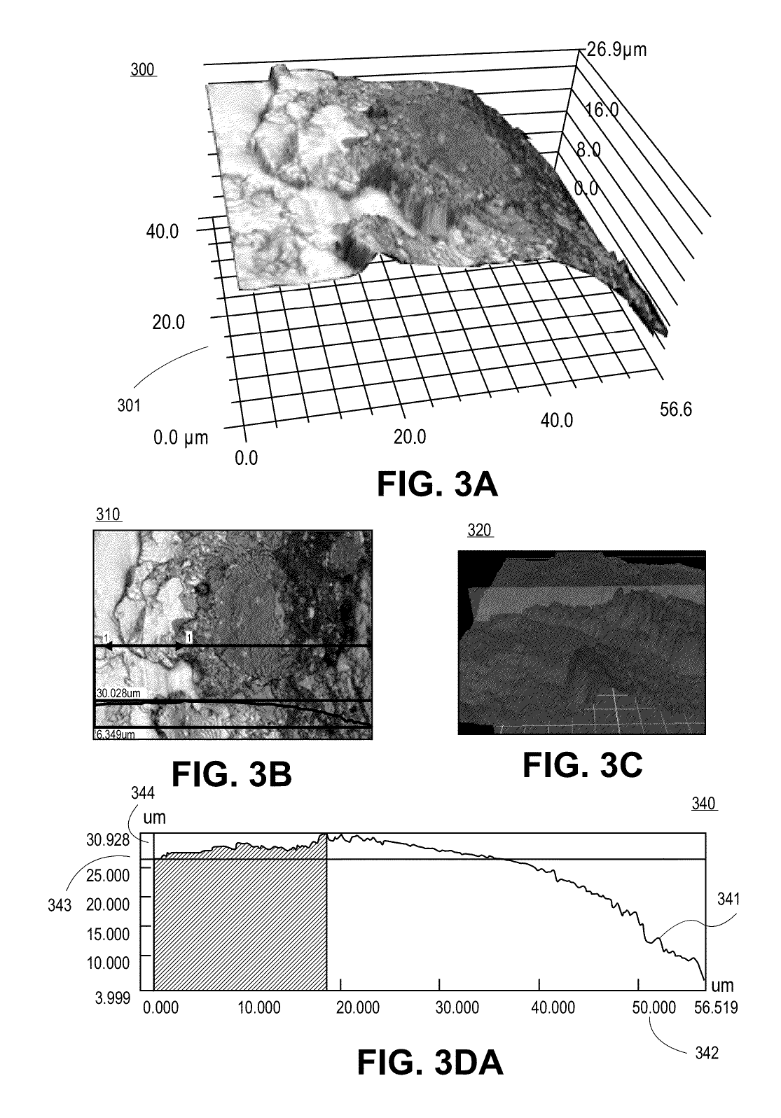

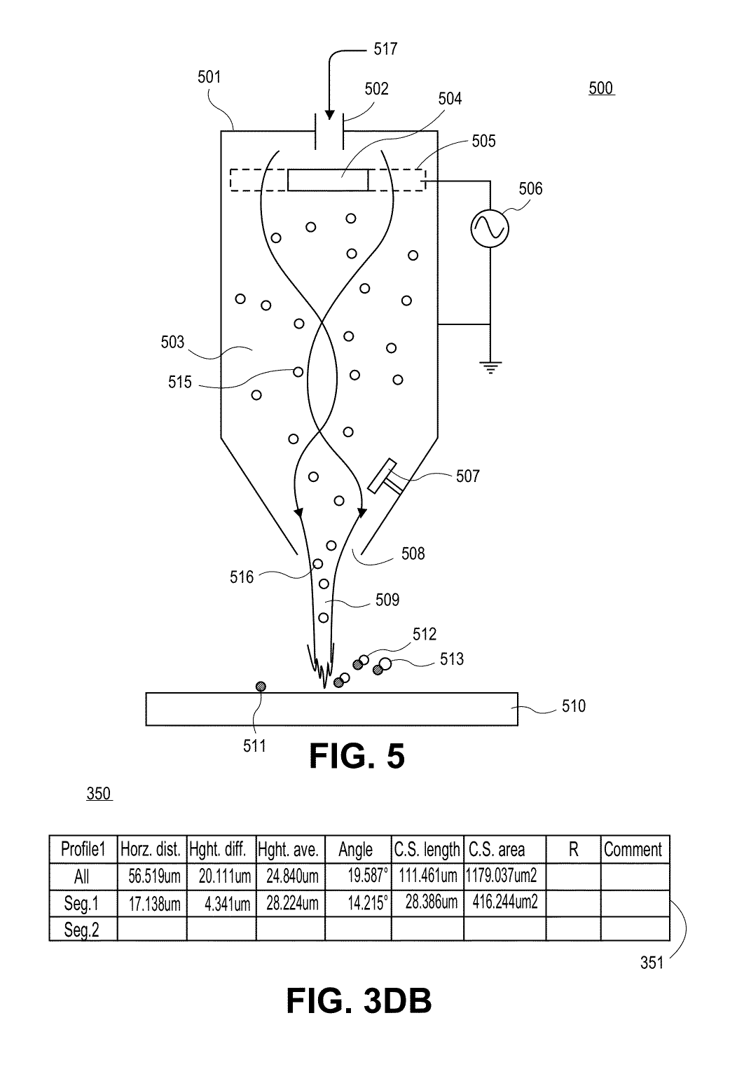

FIG. 3A shows a three dimensional (“3D”) image 300 illustrating a polymer build up detected on an outer seal band edge according to one embodiment. FIG. 3B shows a top view 310 of the image depicted in FIG. 3A. FIG. 3C is a view 320 showing a portion of the 3D image depicted in FIG. 3A. FIG. 3DA is a view 340 showing a graph 341 and FIG. 3DB is a view 350 showing a table 351 illustrating a polymer build up depicted in FIG. 3A. Graph 341 shows the polymer distribution along a vertical axis 343 and a horizontal axis 342. As shown in graph 341 and table 343, the polymer build up has a thickness 344 that is measured to be more than 4 microns (“μm”).

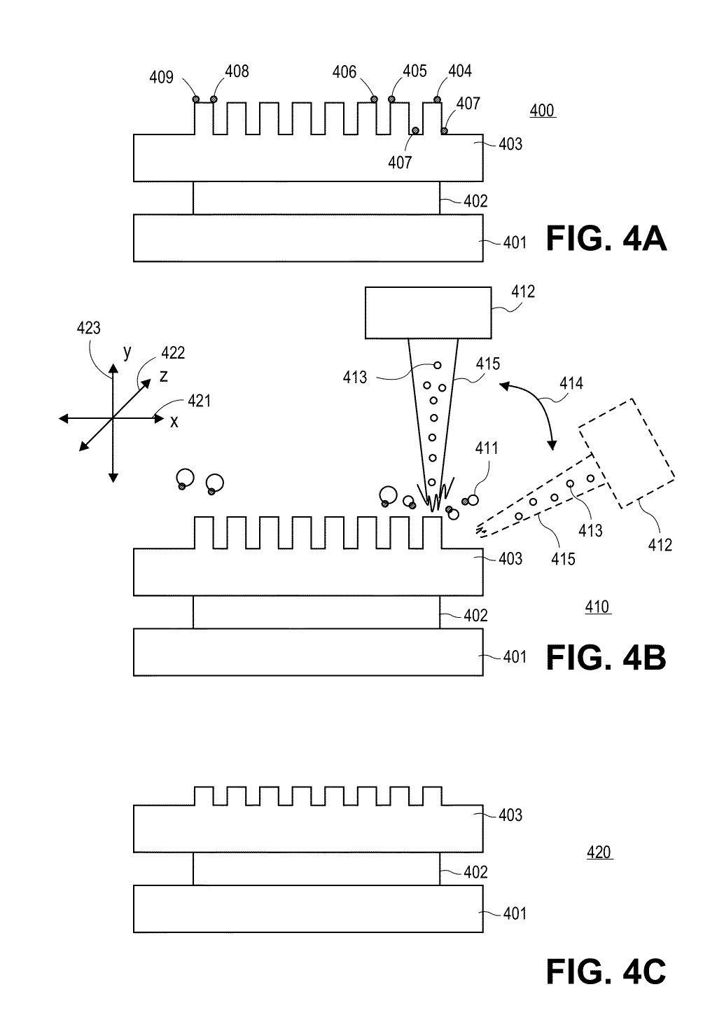

FIG. 4A is a side view 400 illustrating a component 403 placed on a fixture 402 on a stage 401 according to one embodiment. As shown in FIG. 4A, contaminants, such as contaminants 404, 405, 406, 407, 408, and 409 on component 403 are determined, as described above. In an embodiment, the contaminants can be determined by measuring the gas leakage at the component, as described above. The contaminants on the components can be detected using a SEM analysis, a EDS analysis, or any other analysis known to one of ordinary skill in the art of electronic device manufacturing, as described above. In an embodiment, the contaminants are carbon contaminants, organic (e.g., polymer based) contaminants, or both, as described above.

In an embodiment, component 403 represents one of the components of the electronic device manufacturing equipment, as described above. In an embodiment, component 403 comprises a metal, e.g., aluminum and aluminum alloys (e.g. 6061, 5058, etc.), a stainless steel, titanium, a titanium alloy, magnesium, a magnesium, or any other metal and metal alloy known to one of ordinary skill in the art of electronic device manufacturing. In an embodiment, component 403 comprises a ceramic material, for example, an oxide (e.g., aluminum oxide (e.g., Al₂O₃), Yttrium oxide Y₂O₃), an HPM ceramics, an E203 ceramics, and the like) and a nitride (e.g., AIN, etc.) and a glass (e.g., a S102 glass, quartz).

Fixture 402 to hold the component 403 can comprise a metal, such as a cold rolled steel, or any other metal, ceramics such as Al₂O₃, Y₂O₃, or any other ceramics. In an embodiment, fixture 402 has a chucking feature (not shown) to chuck the component 403 for safer and easier handling and cleaning. In an embodiment, fixture 402 has a feature to orient and align component to the plasma jet. Fixture 402 can have a cooling channel, a heating channel, or both to control the component temperature during cleaning. The fixture 402 can have a tilting arrangement (not shown) for maximum cleaning coverage of 3D surfaces e.g., corners, edges, holes, or any other 3D surfaces.

FIG. 4B is a view similar to FIG. 4A, after a plasma jet 415 comprising oxygen plasma particles 413 is generated by a plasma source 412. The oxygen plasma particles are oxygen ions, oxygen radicals, or both. In an embodiment, the oxygen plasma particles are generated from an oxygen containing gas supplied to the plasma source 412. The gas supplied to the plasma source can be an air, a pure oxygen, a mixture of oxygen with reactive gases, a mixture of oxygen with non-reactive gases, or any combination thereof. In an embodiment, an amount of oxygen in the gas supplied to the plasma source is determined based on contaminants (e.g., an amount of contaminants, a type of contaminants, or both). The contaminants are removed from the component 403 by the oxygen plasma particles 413.

As shown in FIG. 4B, the oxygen plasma particles are coupled to contaminant particles to form volatile products, such as volatile products 411 that are evaporated from the surface of the component 403. As shown in FIG. 4B, the plasma source 412 is aligned to the contaminant positioned on the corresponding portion of the component. The plasma source can be aligned with the contaminant by moving the plasma source, moving the component, or both. In an embodiment, at least one of the plasma source 412 and component 403 is moved along or around an X axis 422, an Y axis 423, and a Z axis 422 to remove the contaminants. In an embodiment, component 403 is moved by stage 401. In an embodiment, component 403 is moved by fixture 402.

As shown in FIG. 4B, the plasma source 412 is tilted at an angle 414 to remove the contaminant positioned at the edge corner of the component. In an embodiment, a parameter of the plasma source 412 is adjusted based on the size of the contaminant, location of the contaminant, or both. In an embodiment, the parameters include a voltage supplied to the plasma source, a pressure supplied to the plasma source, a gas supplied to the plasma source, a working distance from the plasma source to the contaminant, a travel speed of the plasma source along the surface of the component, a type of a nozzle of the plasma source (e.g., the nozzle that outputs the plasma jet having a focused plasma beam, or the nozzle that outputs the plasma jet having a substantially parallel plasma beam), an angle of the plasma jet relative to the component, cleaning time duration, temperature, or any combination thereof. In an embodiment, the voltage supplied to the plasma source is in an approximate range from about 10V to about 1000V. In an embodiment, the frequency supplied to the plasma source is in an approximate range 20KHZ to 3GHZ. In an embodiment, the travel speed of the plasma source is from about 0.1 mm/sec to about 20 mm/sec). In a more specific embodiment, the travel speed of the plasma source is about 3 mm/sec. In an embodiment, the cleaning time to remove the contaminant from the component is from about 1 second to about 600 seconds. In a more specific embodiment, the cleaning time to remove the contaminant from the component is about 30 seconds.

In an embodiment, the working distance from the plasma source to the contaminant is from about 0.2 cm to about 4 cm. In a more specific embodiment, the working distance from the plasma source to the contaminant is about 1 cm. In an embodiment, the angle of the plasma jet relative to the component varies from about 0 degree to about 90 degrees. In a more specific embodiment, the angle of the plasma jet relative to the component is from about 35 degrees to about 55 degrees. In an embodiment, the contaminant is removed at an atmospheric pressure. In an embodiment, the contaminant is removed under a vacuum condition, for example, in the vacuum ranging from about 10⁻² to about 10⁻⁷ torr.

FIG. 4C is a view 420 similar to FIG. 4B after cleaning the component according to one embodiment. As shown in FIG. 4C, the contaminants located at the edges, corners, holes, between mesas, and all other contaminants are successfully removed from the component 403 using the oxygen plasma particles in the plasma jet 415. The oxygen plasma cleaning as described herein provides an advantage of effectively removing carbon and organic polymer contaminants located at the edges, corners, holes, between mesas and other portions of the component that cannot be removed by conventional cleaning techniques. In an embodiment, SEM, EDS, or any other analysis technique are used to determine that the contaminants are removed. In an embodiment, the helium leakage as described with respect to FIGS. 1A and 1B is used to determine that the contaminants are removed. Comparing with conventional cleaning techniques, the oxygen plasma cleaning as described herein advantageously reduces the helium leakage at the components of the semiconductor processing chamber by at least a factor of two. Comparing with conventional cleaning techniques, the oxygen plasma cleaning as described herein advantageously reduces the carbon concentration at the edge of the processing chamber component by at least a factor of two. Unlike conventional cleaning techniques, the oxygen plasma cleaning as described herein does not leave any by-products on the processing chamber components. The oxygen plasma cleaning as described herein provides a benefit of effectively cleaning the components outside a processing chamber that substantially reduces the cleaning cost.

FIG. 5 shows a block diagram 500 of an apparatus to clean a component of an electronic device manufacturing equipment according to one embodiment. As shown in FIG. 5, a plasma source 501 is used to direct a plasma jet 509 comprising oxygen plasma particles 516 onto contaminants located on a component 510. A plasma source 501 comprises an inlet 503 to input an oxygen containing gas 517. In an embodiment, the gas 517 is a pure oxygen. In an embodiment, the gas 517 is a mixture of oxygen with other gases, e.g., nitrogen, argon, helium, and other reactive or not reactive gases. In an embodiment, the gas 517 is air.

The gas 517 flows through a swirl system 505 into a plasma chamber 503 to generate a plasma 515. In an embodiment, swirl system 505 comprises a disk and has a ring of passages that are inclined in the circumferential direction. Plasma source 501 comprises a center electrode 504 at swirl system 505, and an outer electrode 507 at a mouth 508. Center electrode 504 is coupled to a voltage generator 506. In an embodiment, the housing of the plasma source 501 is made of an electrically insulating material such as ceramic. Voltage generator 506 provides a voltage to the center electrode 504 to generate plasma 515 to remove contaminants, such as a contaminant 511 from a component 510. In an embodiment, component 510 represents one of the components described above. In an embodiment, contaminant 511 represents one of the contaminants described above.

In an embodiment, the voltage supplied to the center electrode of the plasma source is in an approximate range from about 10V to about 1000V. In an embodiment, the frequency supplied to the center electrode of the plasma source is in an approximate range 20KHZ to 3GHZ. In an embodiment, the voltage supplied to the center electrode of the plasma source is adjusted based on at least one of the size and location of the contaminant. In an embodiment, the travel speed of the plasma source is from about 0.1 mm/sec to about 20 mm/sec). In a more specific embodiment, the travel speed of the plasma source is about 3 mm/sec.

The plasma output through the mouth 508 forms plasma jet 509 comprising oxygen plasma particles 516 such as ions, excited oxygen atoms, excited oxygen molecules, highly reactive oxygen radicals, or any combination thereof. In an embodiment, the strength of the plasma jet 509 is determined by the voltage supplied to the plasma source. All contaminants located on the surface of the component 510 for example, at the edges, corners, holes, between mesas, and other places of the component are chemically bonded to the oxygen plasma particles 516 to form volatile products, such as a volatile product 512 and a volatile product 513 which evaporate from the surface of the component. In an embodiment, carbon and polymer (e.g., organic and non-organic) contaminants are efficiently removed from the edges, corners, holes, between mesas, and other places on the surface of the component by chemically bonding to oxygen plasma particles to form a gas, such as carbon monoxide (“CO”), carbon dioxide (“CO₂”), other gas, or any combination thereof that evaporates from the surface of the component. In an embodiment, plasma source 501 is a plasma nozzle that is held by an arm (not shown) which position is adjustable to allow the plasma nozzle to move in a three dimensional space and tilt relative the component 510.

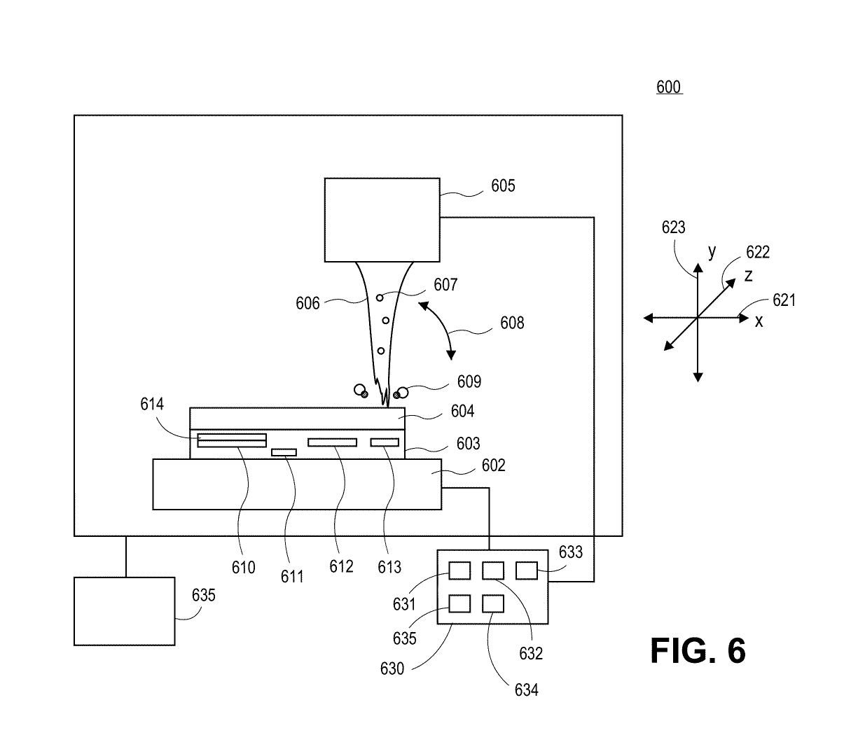

FIG. 6 shows a block diagram 600 of a plasma cleaning system according to one embodiment. As shown in FIG. 6, plasma cleaning system 601 comprises a plasma source 605 to receive a gas comprising oxygen and to generate a plasma jet 606 comprising oxygen plasma particles. Plasma source 605 represents one of the plasma sources described above. A fixture 603 is placed on a stage 602 to hold a component 604. Component 604 represents one of the components described above. In an embodiment, fixture 603 represents one of fixtures described above. The fixture 603 has a DC electrode 612 to chuck the component 604 for safe and easy handling during cleaning. Fixture 603 has an orienting/aligning element 611 to orient/align the components for cleaning. Fixture 603 has a cooling channel 610 and a heating channel 614 to control the component temperature during cleaning. Fixture 603 has a tilting mechanism 613 to tilt the component 603 in a 3D space for effective removal of the contaminants from for example, the edges, corners, holes, between mesas, or other portions of the components.

As shown in FIG. 6, plasma source 605, stage 602, or both can be moved in a 3D space along an X-axis 621, an Y-axis 622, and a Z-axis 623 to remove contaminants from the components, as described above. As shown in FIG. 6, plasma source 605 can be tilted at an angle 608 to remove contaminants from the components. In an embodiment, plasma source 605 represents a plasma nozzle, as described above. In an embodiment, cleaning system 601 removes contaminants from the components at an atmospheric pressure using atmospheric plasma cleaning. Cleaning system 601 can be optionally placed into a vacuum chamber coupled to a vacuum pump 635 to perform cleaning under a vacuum condition, for example, in the vacuum from about 10⁻² torr to about 10-⁷ torr.

A control system 630 is coupled to stage 602 and plasma source 605. Although control system 630 is depicted as controlling both the stage 602, and plasma source 605, in other embodiments, separate control systems can be used to control stage 602 and plasma source 603.

The control system 630 comprises a processor 631, a memory 635, a parameter controller 633, temperature controller 632, input/output devices 634 coupled to the processor 631, coupled to the processor 631. In an embodiment, memory 635 is configured to store parameters to clean the components. The parameters to clean the components are a voltage, a pressure, a gas supplied to the plasma source, a distance to the contaminant, a travel speed, a type of a nozzle of the plasma source (e.g., the nozzle that outputs the plasma jet having a focused plasma beam, or the nozzle that outputs the plasma jet having a substantially parallel plasma beam), an angle of the plasma jet relative to the component (e.g., angle 608), cleaning time, temperature, or any combination thereof. The control system 630 is configured to perform methods as described herein and may be either software or hardware or a combination of both.

The control system 630 has a first configuration to control the plasma source 605 to remove a contaminant from the component 604 using the oxygen plasma particles, as described above. The control system 630 has a second configuration to determine the contaminant on the component. The control system 630 has a third configuration to adjust the parameter of the plasma source based on the contaminant. The control system 630 has a fourth configuration to align the contaminant on the component to the plasma source.

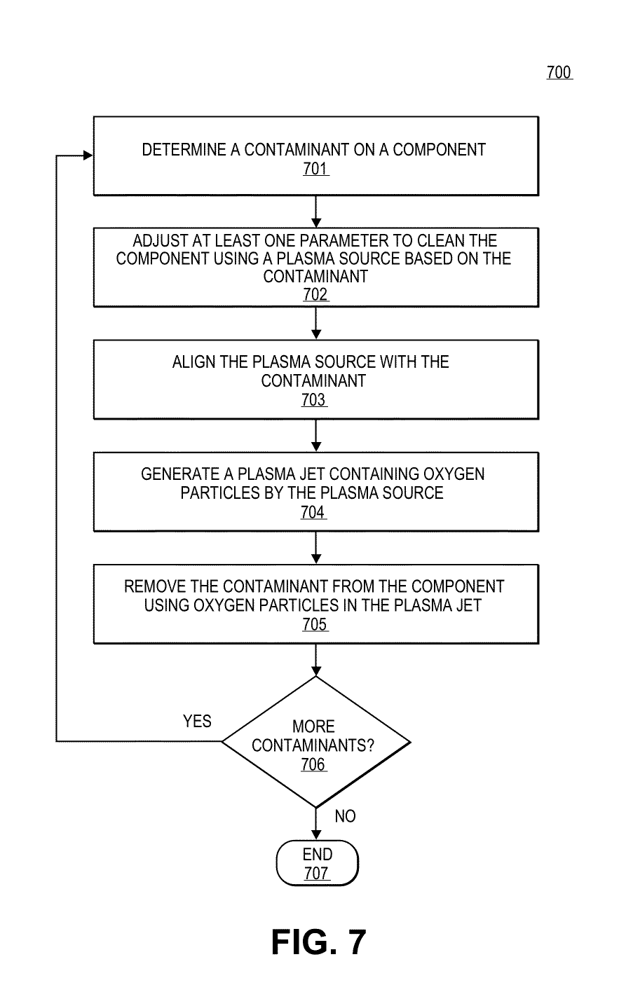

FIG. 7 is a flow chart of a method 700 to clean a component of an electronic device manufacturing equipment according to one embodiment. At a block 701 a contaminant on a component is determined, as described above. In an embodiment, the size, the location of the contaminant on the component, or both are determined, as described above. In an embodiment, the contaminant on the component of a processing chamber is determined after about every 40-60 hours of operation. At a block 702 at least one parameter associated with cleaning the component by a plasma source is adjusted based on at least one of the size and location of the contaminant, as described above. In an embodiment, the component is placed on a stage and stabilized using the fixture, as described above. In an embodiment, the parameters to clean the components are a voltage, a pressure, a gas supplied to the plasma source, a distance to the contaminant, a travel speed, a type of a nozzle of the plasma source (e.g., the nozzle that outputs the plasma jet having a focused plasma beam, or the nozzle that outputs the plasma jet having a substantially parallel plasma beam), an angle of the plasma jet relative to the component, cleaning time, temperature, or any combination thereof. At a block 703 the plasma source is aligned with the contaminant on the component. In an embodiment, aligning involves moving the plasma source, the component, or both, as described above. At a block 704 a plasma jet comprising oxygen plasma particles is generated by the plasma source, as described above. In an embodiment, a flow of the oxygen containing gas is supplied to the plasma source, a voltage is applied to the central electrode of the plasma source, plasma is generated and stabilized for a predetermined time (e.g., few seconds) to output a plasma jet comprising oxygen plasma particles, as described above.

At a block 705 the contaminant is removed from the component by the oxygen plasma particles in the plasma jet, as described above. At a block 706 it is determined if there are more contaminants. If there are more contaminants, method returns to block 701. The blocks 701-705 are repeated until all contaminants are removed. If all contaminants are removed from the component, method ends at a block 707.

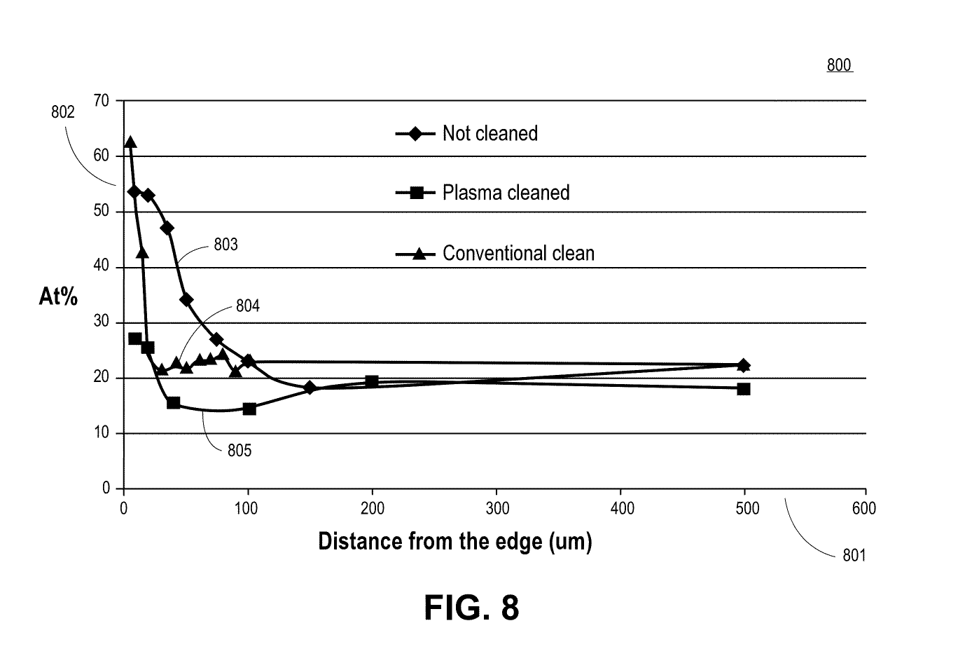

FIG. 8 is a view 800 illustrating curves 803, 804, and 805 showing a concentration of the carbon contaminants (“At %”) 802 measured versus a distance from an edge of a component 801 according to one embodiment. Curve 803 is obtained when the component is not cleaned. Curve 803 shows very high carbon concentration at the edge of the component. Curve 804 is obtained after a conventional cleaning process. Curve 804 shows that after the conventional cleaning process the carbon concentration at the edge of the component increases as a result of the by-product deposition. Curve 805 is obtained using oxygen plasma cleaning using methods as described herein. Curve 805 shows that the carbon concentration at the edge of the component is reduced by at least a factor of two. That is, the oxygen plasma cleaning as described herein advantageously removes the high carbon concentration at the edge of the component that cannot be removed by conventional cleaning techniques.

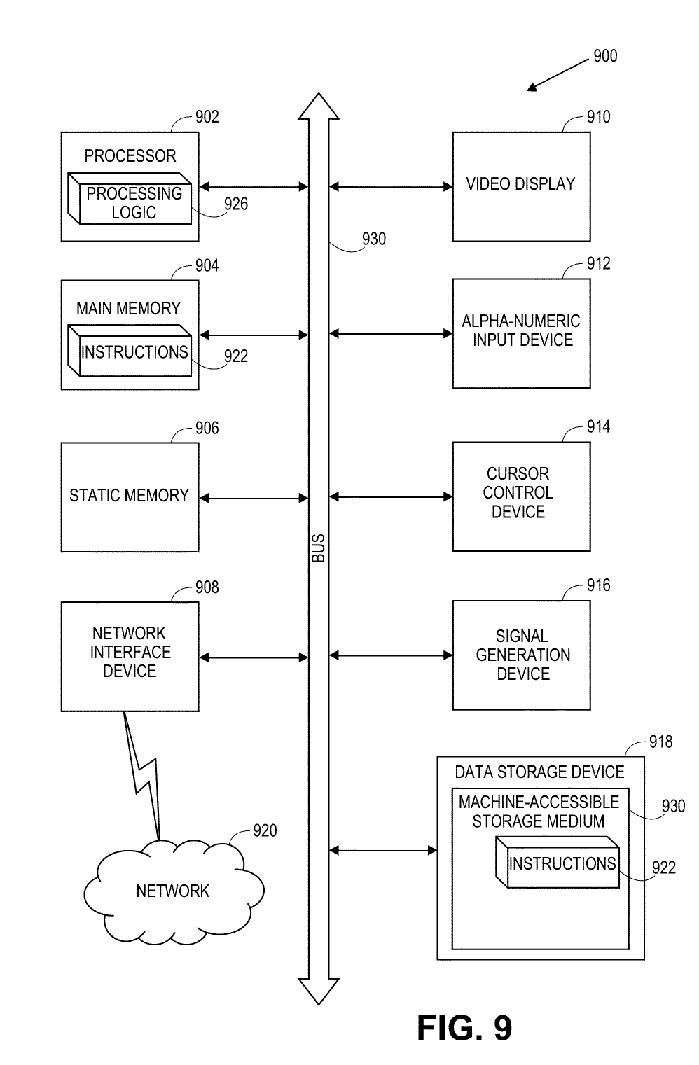

FIG. 9 shows a block diagram of an embodiment of a data processing system 900 to control the plasma cleaning system as described herein. Data processing system processing 900 can represent control system 630. In at least some embodiments, the data processing system controls the oxygen plasma cleaning system to perform operations involving supplying a gas comprising oxygen to a plasma source, generating a plasma jet comprising oxygen plasma particles from the gas; and removing a contaminant from the component using the oxygen plasma particles, as described herein.

In alternative embodiments, the data processing system may be connected (e.g., networked) to other machines in a Local Area Network (LAN), an intranet, an extranet, or the Internet. The data processing system may operate in the capacity of a server or a client machine in a client-server network environment, or as a peer machine in a peer-to-peer (or distributed) network environment.

The data processing system may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that data processing system. Further, while only a single data processing system is illustrated, the term “data processing system” shall also be taken to include any collection of data processing systems that individually or jointly execute a set (or multiple sets) of instructions to perform any one or more of the methodologies described herein.

The exemplary data processing system 900 includes a processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device), which communicate with each other via a bus 930.

Processor 902 represents one or more general-purpose processing devices such as a microprocessor, central processing unit, or the like. More particularly, the processor 902 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 902 may also be one or more special-purpose processing devices such as an application specific integrated circuit (ASIC), a field programmable gate array (FPGA), a digital signal processor (DSP), network processor, or the like. Processor 902 is configured to execute the processing logic 926 for performing the operations described herein.

The computer system 900 may further include a network interface device 908. The computer system 900 also may include a video display unit 910 (e.g., a liquid crystal display (LCD), a light emitting diode display (LED), a cathode ray tube (CRT), etc.), an alphanumeric input device 912 (e.g., a keyboard), a cursor control device 914 (e.g., a mouse), and a signal generation device 916 (e.g., a speaker).

The secondary memory 918 may include a machine-accessible storage medium (or more specifically a computer-readable storage medium) 930 on which is stored one or more sets of instructions (e.g., software 922) embodying any one or more of the methodologies or functions described herein. The software 922 may also reside, completely or at least partially, within the main memory 904 and/or within the processor 902 during execution thereof by the computer system 900, the main memory 904 and the processor 902 also constituting machine-readable storage media. The software 922 may further be transmitted or received over a network 920 via the network interface device 908.

While the machine-accessible storage medium 930 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

In the foregoing specification, embodiments of the invention have been described with reference to specific exemplary embodiments thereof. It will be evident that various modifications may be made thereto without departing from the broader spirit and scope of embodiments of the invention as set forth in the following claims. The specification and drawings are, accordingly, to be regarded in an illustrative sense rather than a restrictive sense.

What is claimed is:

1. A method to clean a component of an electronic device manufacturing equipment comprising:
supplying a gas comprising oxygen to a plasma source;
generating a plasma jet comprising oxygen plasma particles from the gas; and
removing a contaminant from the component using the oxygen plasma particles.

2. The method of claim 1, wherein removing comprises transforming the contaminant into a volatile product using the oxygen plasma particles.

3. The method of claim 1, wherein the gas is an air, a pure oxygen, a mixture of oxygen with reactive gases, a mixture of oxygen with non-reactive gases, or any combination thereof.

4. The method of claim 1, wherein the component is an electrostatic chuck, a nozzle, a showerhead, a chamber liner, a cathode sleeve, a sleeve liner door, a cathode base, a process ring, or any other component of a processing chamber for the electronic device manufacturing.

5. The method of claim 1, further comprising determining the contaminant on the component;
adjusting a parameter of the plasma source based on the contaminant; and
aligning the contaminant on the component to the plasma source.

6. The method of claim 1, wherein the contaminant comprises at least one of a carbon and an organic material.

7. The method of claim 1, wherein the contaminant is removed under one of a vacuum and an atmospheric pressure.

8. An apparatus to clean a component of an electronic device manufacturing equipment comprising:
a fixture to hold the component;
a plasma source to receive a gas comprising oxygen and to generate a plasma jet comprising oxygen plasma particles from the gas; and
a processor coupled to the plasma source, wherein the processor has a first configuration to control the plasma source to remove a contaminant from the component using the oxygen plasma particles.

9. The apparatus of claim 8, wherein the oxygen particles in the plasma jet are used to transform the contaminant into a volatile product.

10. The apparatus of claim 8, wherein the gas is an air, a pure oxygen, a mixture of oxygen with reactive gases, a mixture of oxygen with non-reactive gases, or any combination thereof.

11. The apparatus of claim 8, wherein the component is an electrostatic chuck, a nozzle, a showerhead, a chamber liner, a cathode sleeve, a sleeve liner door, a cathode base, a process ring, or any other component of a processing chamber for the electronic device manufacturing.

12. The apparatus of claim 8, further comprising a memory coupled to the processor to store a parameter of the plasma source, and wherein the processor has a second configuration to determine the contaminant on the component, wherein the processor has a third configuration to adjust the parameter of the plasma source based on the contaminant, and the processor has a fourth configuration to align the contaminant on the component to the plasma source.

13. The apparatus of claim 8, wherein the contaminant comprises at least one of a carbon and an organic material.

14. The apparatus of claim 8, wherein the contaminant is removed under one of a vacuum and an atmospheric pressure.

15. A method to clean a component of an electronic device manufacturing equipment comprising:
determining a contaminant on the component;
adjusting at least one parameter of a plasma source based on the contaminant;
aligning the plasma source with the contaminant;
generating a plasma jet comprising oxygen plasma particles by the plasma source; and
removing the contaminant from the component by the oxygen plasma particles in the plasma jet.

16. The method of claim 15, wherein removing comprises transforming the contaminant into a volatile product using the oxygen plasma particles.

17. The method of claim 15, wherein the at least one parameter is a voltage, a pressure, a gas supplied to the plasma source, a distance to the contaminant, a travel speed, a type of a nozzle of the plasma source, an angle of the plasma jet, cleaning time, temperature, or any combination thereof.

18. The method of claim 15, wherein the contaminant is determined by measuring a helium leakage at the component.

19. The method of claim 15, wherein the plasma source is aligned with the contaminant by moving at least one of the plasma source and the component.

20. The method of claim 15, wherein the contaminant comprises at least one of a carbon and an organic material.
